(19) United States
(12) Patent Application Publication
(10) Pub. No.: US 2024/0167160 A1
(43) Pub. Date: May 23, 2024

(54) SYSTEMS AND APPARATUS FOR SEMICONDUCTOR EQUIPMENT

(71) Applicant: ASM IP Holding B.V., Almere (NL)

(72) Inventors: Ankit Kimtee, Phoenix, AZ (US); Sudhanshu Biyani, Tempe, AZ (US); Kyle Fondurulia, Phoenix, AZ (US); Yeonsu Rhee, Phoenix, AZ (US); Shubham Garg, Gilbert, AZ (US)

(21) Appl. No.: 18/510,043

(22) Filed: Nov. 15, 2023

Related U.S. Application Data
(60) Provisional application No. 63/426,448, filed on Nov. 18, 2022.

(51) Int. Cl. C23C 16/455; C23C 16/458; C23C 16/46

(52) U.S. Cl. CPC C23C 16/45591; C23C 16/4585; C23C 16/4586; C23C 16/46

(57) ABSTRACT

Various embodiments of the present technology may provide a feature to isolate an upper chamber of a reaction chamber from a lower chamber of a reaction chamber. In one case, a susceptor has a groove along an outer edge that is configured to mate with a spacer plate. A seal is disposed in the groove. In another case, a flow control ring, which rests on the susceptor, has a groove along an outer edge that is configured to mate with the spacer plate.

### CROSS-REFERENCE TO RELATED APPLICATIONS

This application is a nonprovisional of, and claims priority to and the benefit of, U.S. Provisional Patent Application No. 63/426,448, filed Nov. 18, 2022 and entitled “SYSTEMS AND APPARATUS FOR SEMICONDUCTOR EQUIPMENT,” which is hereby incorporated by reference herein.

### FIELD OF INVENTION

The present disclosure generally relates to an apparatus for semiconductor equipment. More particularly, the present disclosure relates to a sealing feature within a reaction chamber used during the fabrication of semiconductor devices.

### BACKGROUND OF THE TECHNOLOGY

Equipment used during the semiconductor manufacturing process may provide a susceptor heater to support a wafer within a reaction chamber. The reaction chamber may have an upper chamber and a lower chamber. During processing of the wafer, it may be desired to isolate the lower chamber from the upper chamber to prevent chemicals from entering and/or deposition from occurring in the lower chamber.

### SUMMARY OF THE INVENTION

Various embodiments of the present technology may provide a feature to isolate an upper chamber of a reaction chamber from a lower chamber of a reaction chamber. In one case, a susceptor has a groove along an outer edge that is configured to mate with a spacer plate. A seal is disposed in the groove. In another case, a flow control ring, which rests on the susceptor, has a groove along an outer edge that is configured to mate with the spacer plate.

According to one aspect, a reaction chamber comprises: a lower chamber having an interior space defined by a bottom surface and horizontally-oriented sidewalls that extend upwards from the bottom surface; a lid opposite from the bottom surface and in direct contact with the sidewalls, wherein the lid comprises an opening; a spacer plate, comprising: a first end connected to the lid; and a second end extending towards the opening of the lid, wherein the second end comprises a horizontally-oriented section and a ridge extending downward from the horizontally-oriented section; a susceptor, comprising: a primary region comprising a heating element; and an outer edge extending away from the primary region, wherein the outer edge comprises a groove that is sized to mate with the ridge; and a seal positioned within the groove.

In one embodiment of the above reaction chamber, the spacer plate is connected to the lid with a fastener formed from a non-conducting material.

In one embodiment of the above reaction chamber, the reaction chamber further comprises an electrical insulator disposed between the spacer plate and the lid.

In one embodiment of the above reaction chamber, the seal comprises an e-ring formed from a metal material.

In one embodiment of the above reaction chamber, the seal contacts the ridge of the spacer plate.

In one embodiment of the above reaction chamber, the groove and the ridge have complementary shapes.

According to another aspect, a reaction chamber comprises: a lower chamber having an interior space defined by a bottom surface and horizontally-oriented sidewalls that extend upwards from the bottom surface; a lid opposite from the bottom surface and in direct contact with the sidewalls, wherein the lid comprises an opening; a spacer plate, comprising: a first end connected to the lid; and a second end extending towards the opening of the lid, wherein the second end comprises a horizontally-oriented section and a ridge extending downward from the horizontally-oriented section; a susceptor, comprising: a primary region comprising a heating element and having a first height; and an outer edge extending horizontally away from the primary region, wherein the outer edge has second height that is less than the first height; a flow control ring positioned on the outer edge and comprising an upward facing surface; and a seal positioned on the flow control ring.

In one embodiment of the above reaction chamber, the flow control ring comprises a groove within the upward facing surface.

In one embodiment of the above reaction chamber, the groove is sized to mate with the ridge.

In one embodiment of the above reaction chamber, the groove and the ridge have complementary shapes.

In one embodiment of the above reaction chamber, the seal is disposed within the groove.

In one embodiment of the above reaction chamber, the seal comprises an e-ring formed from a metallic material.

In one embodiment of the above reaction chamber, the seal contacts the ridge of the spacer plate.

In yet another aspect, a reaction chamber comprises: a lower chamber having an interior space defined by a bottom surface and horizontally-oriented sidewalls that extend upwards from the bottom surface; a lid opposite from the bottom surface and in direct contact with the sidewalls, wherein the lid comprises an opening; a spacer plate, comprising: a first end connected to the lid; and a second end extending towards the opening of the lid, wherein the second end comprises a horizontally-oriented section and a first ridge extending downward from the horizontally-oriented section; a susceptor, comprising: a primary region comprising a heating element and having a first height; and an outer edge, having a second height that is less than the first height, extending away from the primary region, and an e-ring seal disposed between the first ridge and the outer edge.

In one embodiment of the above reaction chamber, the reaction chamber further comprises a flow control ring positioned on the outer edge and comprising an upward facing surface.

In one embodiment of the above reaction chamber, upward facing surface comprises a groove that is sized to mate with the first ridge.

In one embodiment of the above reaction chamber, the susceptor further comprises a second ridge extending upwards from the outer edge, and wherein the groove is formed by a vertical sidewall of the primary region and the second ridge.

In one embodiment of the above reaction chamber, the groove and the first ridge have complementary shapes.

In one embodiment of the above reaction chamber, the spacer plate is connected to the lid with a fastener formed from a non-conducting material.

In one embodiment of the above reaction chamber, the reaction chamber further comprises an electrical insulator disposed between the spacer plate and the lid.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a cross sectional view of a system in accordance with an exemplary embodiment of the present technology;

FIG. 2 representatively illustrates is a cross sectional view of an alternative system in accordance with an exemplary embodiment of the present technology;

FIG. 3 is a cross sectional view of a portion of the system in accordance with an exemplary embodiment of the present technology;

FIG. 4 is a cross sectional view of a portion of a system in accordance with an alternative embodiment of the present technology;

FIG. 5 is a top-down view of the embodiment of FIG. 3;

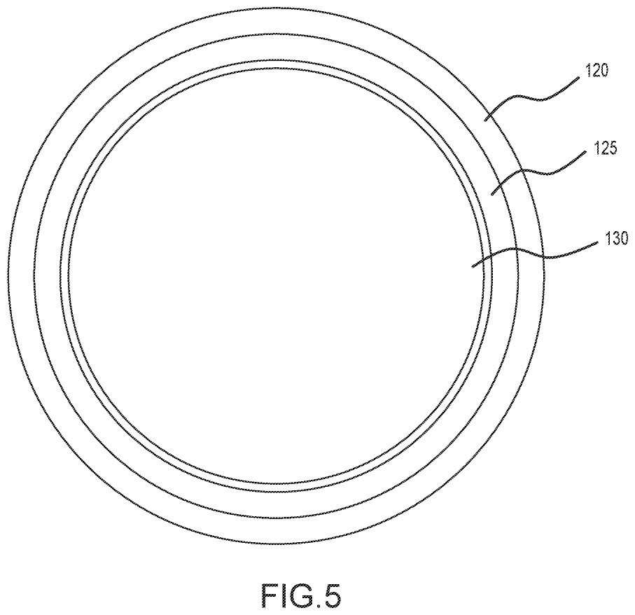

FIG. 6 is a top-down view of the embodiment of FIG. 4;

FIG. 7 is a cross-sectional view of a portion of the system in accordance with an embodiment of the present technology; and

FIG. 8 is a cross-sectional view of a portion of the system in accordance with an embodiment of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various showerheads, susceptor pedestals, and lids. Further, the present technology may employ any number materials suitable for a particular application.

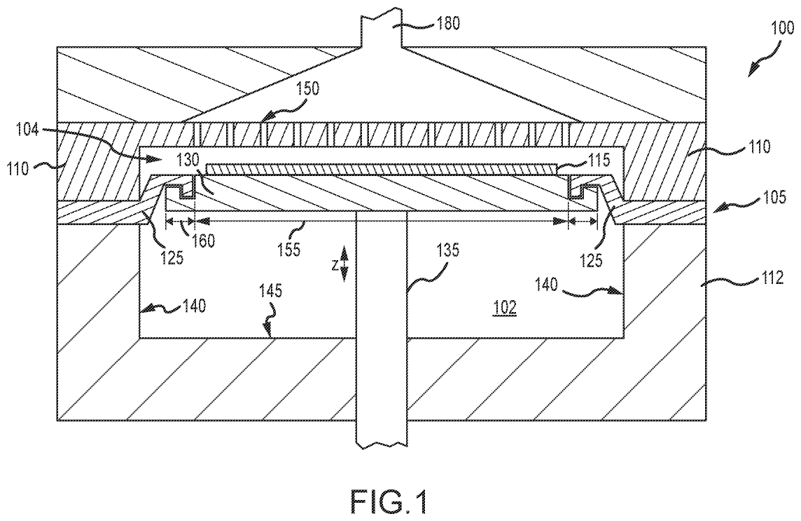

Referring to FIG. 1, an exemplary system 100 may comprise a reaction chamber 105 for processing a substrate, such as a wafer 115. The reaction chamber 105 may comprise a lower chamber 112 and a showerhead 110. The lower chamber 112 may comprise a horizontally-oriented bottom surface 145 and vertically-oriented sidewalls 140 extending upwards from the horizontally-oriented bottom surface 145. In various embodiments, the lower chamber 120 may be formed from a metal, such as aluminum.

The reaction chamber 105 may comprise an interior space comprising a lower interior space 102 and an upper interior space 104. The lower interior space 103 may defined by the lower chamber 112 (e.g., the vertically-oriented sidewalls 140 and a horizontally-oriented bottom surface 140), and the susceptor 130. The upper interior space 104 may be defined by the space between the susceptor 130 and the showerhead 110.

The system 100 may further comprise an inlet 180 to deliver various precursors to the reaction chamber 105 via the showerhead 110.

The showerhead 110 may comprise a plurality of through-holes 150 configured to flow precursor from the inlet 180 toward the wafer 115. The showerhead 110 may be positioned adjacent to and supported by the sidewall 140 of the lower chamber 112.

The system 100 may further comprise a susceptor 130 disposed within the interior space 102 of the reaction chamber 100 and configured to support the wafer 115. The susceptor 130 may be supported by a pedestal 135. In various embodiments, the susceptor 130 may be configured to move up and down along a z-axis (Z), for example from a first position to a second position.

In various embodiments, the susceptor 130 may be formed from ceramic (alumina, AlOx), or a metal (e.g., stainless steel, Hastelloy, or the like). The susceptor 130 may comprise a top surface that is horizontally-oriented and positioned directly below the showerhead 110. The wafer 115 (or other substrate) may rest on the top surface of the susceptor 130 during processing. In some embodiments, the susceptor 130 may comprise a plurality of electrodes (not shown) embedded therein to generate an electric field to provide an electrostatic chucking function.

The susceptor 130 may comprise a heating element (not shown) configured to heat the wafer 115 to any desirable temperature during processing. The heating element may comprise any suitable heating element and may be arranged in any desired shape or pattern. In various embodiments, the susceptor 130 may further comprise through-holes (not shown) for which lift pins (not shown) may be disposed within.

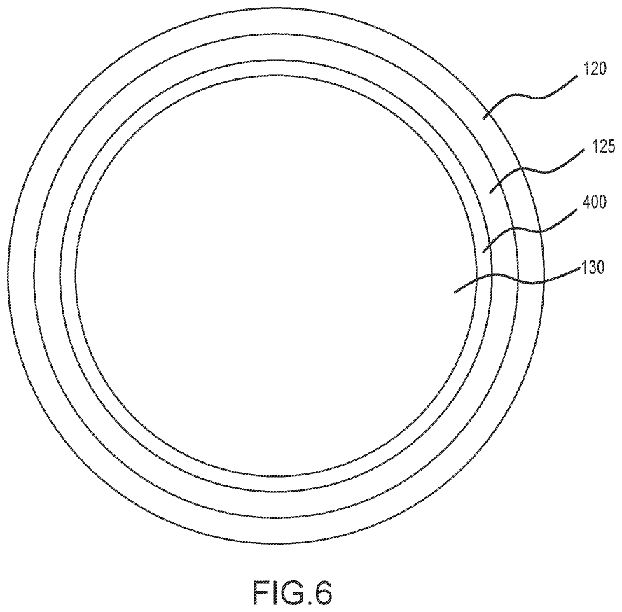

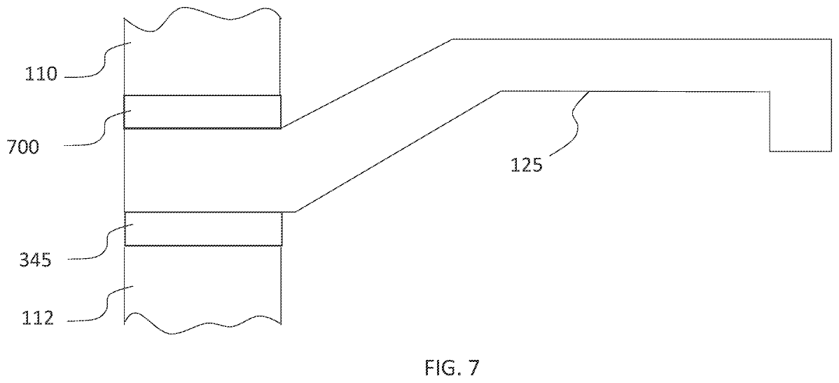

In various embodiments, the susceptor 130 is round (e.g., as illustrated in FIGS. 6 and 7) and has a primary region 155, for example the area used to support the wafer 115, and a secondary region 160 along the outer edge of the primary region 155. The primary region 155 may be circular and the secondary region 160 may extend from and be concentric with the primary region 155. In other words, the secondary region 160 may encircle the primary region 155. In various embodiments, the heating element may be arranged within the primary region 155. The primary region 155 may have a first height H1 and the secondary region 160 may have a second height H2, where the first height H1 is greater than the second height H2. In various embodiments, the first height H1 may range from 10 mm to 30 mm and the second height H2 may range from 3 mm to 8 mm. In addition, in some embodiments, the second region 160 may comprise a first groove 350 formed by a first ridge 360 (i.e., a lip) extending upwards from the secondary region 160 and a vertical sidewall 365 of the primary region 155.

The system 100 may further comprise a spacer plate 125 to facilitate isolation of the lower interior space 102 from the upper interior space 104. In various embodiments, the spacer plate 125 may be disposed between the lower chamber 112 and the showerhead 110 and extend inward into the interior space of the reaction chamber 105. In various embodiments, the spacer plate 125 may surround or otherwise encircle the susceptor 130 (e.g., as illustrated in FIGS. 6 and 7).

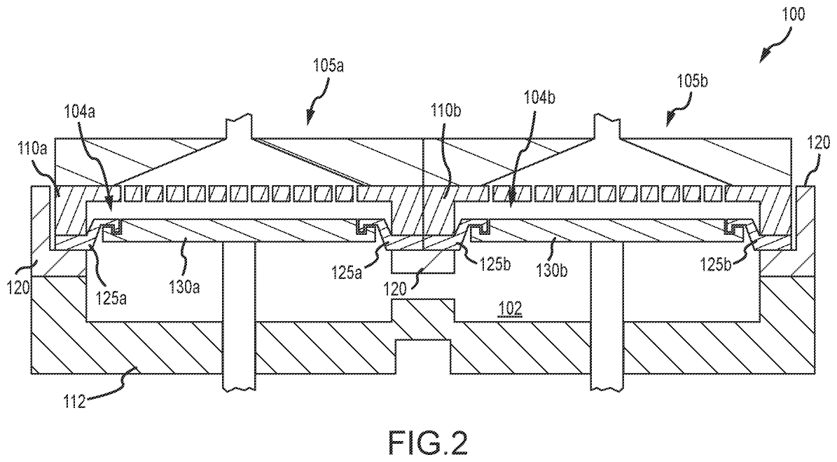

Referring to FIG. 2, the system 100 may comprise a plurality of reaction chambers, such as a first reaction chamber 105(a) and a second reaction chamber 105(b). In the present case, the reaction chambers 105(a), 105(b) may be adjacent to each other and share a lower chamber 112 and lower interior space 102. The lower chamber 112 may be formed from a metal material, such as elemental aluminum or any metal alloy. The first reaction chamber 105(a) may comprise a first susceptor 130(a), a first showerhead 110(a), a first spacer plate 125(a), and a first upper interior space 104(a). Similarly, the second reaction chamber 105(a) may comprise a second susceptor 130(b), a second showerhead 110(b), a second spacer plate 125(b), and a second upper interior space 104(b). The first upper interior space 104(a) is isolated from the second upper interior space 104(b).

In the present case, the system 100 may further comprise a lid 120 to support the first and second spacer plates 125(a), 125(b) and the first and second showerheads 110(a), 110(b). In various embodiments, the lid 120 may be directly adjacent to the lower chamber 112, such that the sidewalls of the lower chamber 112 support the lid 120. The lid 120 may have a first opening to allow the first susceptor 130(a) to move from the first position in the lower interior space 102 to the second position in the upper interior space 104. In addition, the lid 120 may have a second opening to allow the second susceptor 130(b) to move from the first position in the lower interior space 102 to the second position in the upper interior space 104. In various embodiments, the lid 120 may formed from aluminum and may be physically attached or fastened (e.g., by bolts or screws) to the lower chamber 112. In other cases, however, the lid 120 may rest on top of the lower 112 without being physically attached.

It should be noted that the susceptors 130(a), 130(b) are illustrated in the second position in FIG. 2, wherein the susceptor 130 and the spacer plate 125 are aligned to separate and isolate the lower interior space 102 from the upper interior space 104. When the susceptor 130 is in the first position, the susceptor 130 is positioned further into the lower interior space 102.

In various embodiments, the susceptors 130(a), 130(b) can move independently from each other. For example, one susceptor may be in the first position while the other susceptor is in the second position.

In various embodiments, and referring to FIGS. 1-4, the spacer plate 125 may comprise first end 300 and a second end 300. The first end 300 and second end 305 may be separated by an arm 310 having a slanted section 320 and a horizontally-oriented section 315. The slanted section 320 may extend from the first end 300 and be followed by the horizontally-oriented section 315. The spacer plate 125 may further comprise a second ridge 325 (i.e., a lip) extending downward from the second end 305. For example, the second ridge 325 may extend downward from the horizontally-oriented section 315. The second ridge 325 may extend along the entire circumference of the second end 305 of the spacer plate 125.

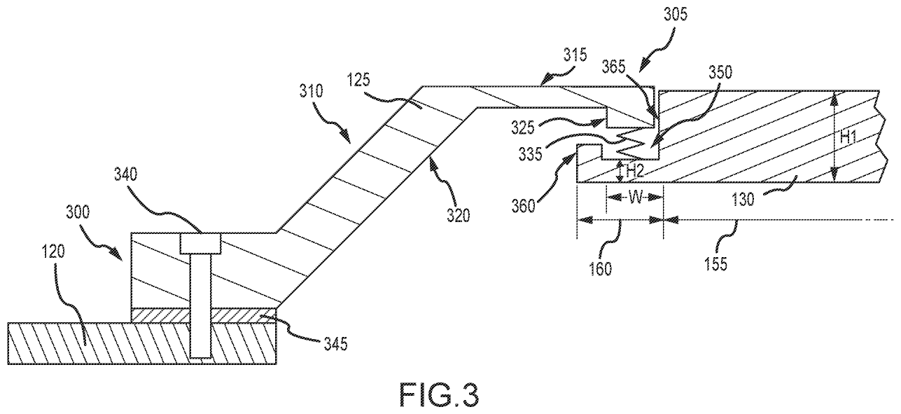

In various embodiments, the first end 300 may be attached directly to the lid 120 (e.g., as illustrated in FIG. 3) with a fastener, such as a screw 340 or other suitable hardware. Alternatively, the lid 120 may be omitted and the spacer plate 125 may be attached directly to the lower chamber 112 (e.g., as illustrated in FIG. 1) with any suitable fastener or may rest on the lower chamber 112 without a physical attachment.

Referring to FIG. 3, in various embodiments, the spacer plate 125 and the susceptor 130 may be configured to form a seal to isolate the upper interior space 104 from the lower interior space 102 when the susceptor 103 is in the second position. In an exemplary embodiment, the spacer plate 125 mates with the susceptor 130. For example, the second ridge 325 may be sized to fit within the first groove 350 of the susceptor 130. In other words, the first groove 350 and the second ridge 325 may have complementary shapes. The first groove 350 may have a width W in the range of 4 mm to 12 mm. Accordingly, the width of the second ridge 325 may be slightly less than the width W of the first groove 350.

In addition, the system 100 may further comprise a sealing member 335 positioned between the second ridge 325 and the outer edge 160. In particular, the sealing member 335 may be disposed within the first groove 350. The sealing member 335 may be a metallic (i.e., of a metal material) seal, such as an e-ring seal, or any other suitable metallic seal having flexibility, high temperature capability, and low compression loading.

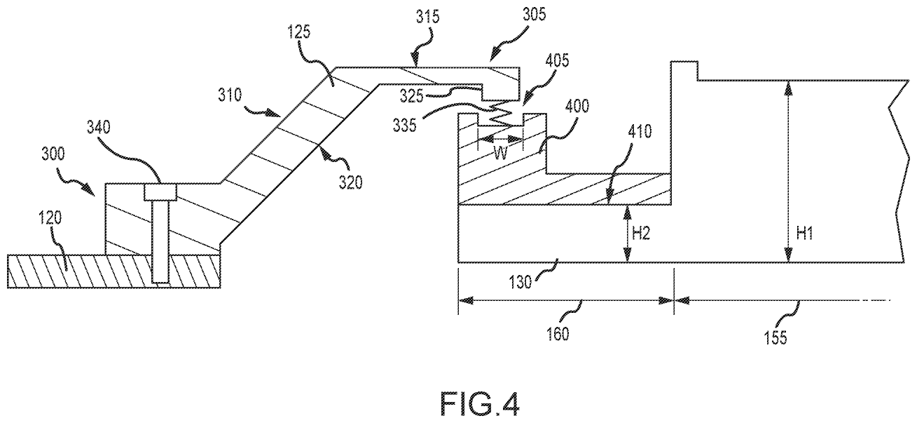

Referring to FIG. 4, in various embodiments, the system 100 may further comprise a flow control ring 400 disposed on the susceptor 130. For example, the flow control ring 400 may sit flush with a top surface 410 of the outer edge 160 of the susceptor 130. The flow control ring 400 may comprise a second groove 405 disposed in an upward facing surface of the flow control ring 400. In an exemplary embodiment, the second groove 405 may align with and be shaped to mate with (or otherwise fit within) the second ridge 325 of the spacer plate 125. In other words, the second groove 405 and the second ridge 325 may have complementary shapes. The second groove 405 may have a width W in the range of 4 mm to 12 mm. Accordingly, the width of the second ridge 325 may be slightly less (e.g., 1-2 mm less) than the width W of the second groove 405. In the present embodiment, the flow control ring 400 may electrically isolate the susceptor 130 from the spacer plate 125. Accordingly, the flow control ring 400 may be formed from a material that has electrically insulative properties, such as quartz, polyether ether ketone (PEEK), polyetherimide, mica-based plastics, or the like.

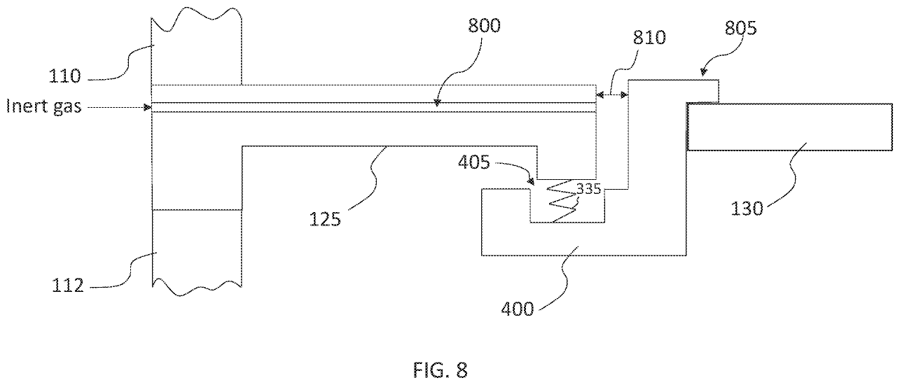

In various embodiments, and referring to FIG. 8, the spacer plate 125 may comprise a through-hole 800 configured to flow a gas, such as an inert gas (e.g., argon or nitrogen). For example, the through-hole 800 may extend linearly and horizontally through the entire length of the spacer plate 125. Alternatively, the through-hole 800 may extend through a portion of the spacer plate 125 and comprise angles or curves. A first end of the through-hole 800 may be coupled to a gas line (not shown) to deliver the inert gas. The first end of the through-hole 800 may be on an exterior of the reaction chamber 105, while the a second end (opposite the first end) may be on an interior of the reaction chamber 105. The second end may be arranged in a location that provides flowing of the inert gas near and/or towards the sealing member 335, spacer plate 125, and the second groove 405.

In addition, in the present case, the flow control ring 400 may comprise an “S” shape. For example, the flow control ring 400 may comprise a vertical section extending upwards and a protrusion 805 that overlaps a top surface of the susceptor 130. In addition, the surface of the spacer plate 125 that includes the second end of the through-hole 800 may be spaced apart from the flow control ring 400 by a gap 810. The gap 810 may range from 0.5 mm to 5 mm.

In various embodiments, the system 100 may further comprise a first insulator 345 disposed between the lid 120 (or the lower chamber 112) and the spacer plate 125 to electrically isolate the lid 120 or lower chamber 112 from the spacer plate 125 and/or susceptor 130 (e.g., as illustrated in FIG. 3). For example, the first insulator 345 may be disposed between the first end 300 of the spacer plate 125 and the lid 120 or lower chamber 112. In other embodiments where the lid 120 and the flow control ring 400 are omitted, the first insulator 345 may be disposed between the spacer plate 125 and the lower chamber 112 to electrically isolate the susceptor 130 from the lower chamber 112. The first insulator 345 may comprise any material suitable for electrical isolation, such as quartz, polyether ether ketone (PEEK), polyetherimide, mica-based plastics, ceramic, or the like.

In various embodiments, and referring to FIG. 7, the system 100 may further comprise a second insulator 700 disposed between the spacer plate 125 and the showerhead 110. The second insulator 700 may comprise any material suitable for electrical isolation, such as quartz, polyether ether ketone (PEEK), polyetherimide, mica-based plastics, ceramic, or the like.

In operation, as the susceptor 130 moves up along the z-direction, the sealing member 335 compresses between the spacer plate 125 and the flow control ring 400 or the susceptor 130. The sealing member 335 in combination with the geometry of the spacer plate 125 and complementary shaped flow control ring 400 or susceptor 130, a seal is formed between the spacer plate 125 and the flow control 400 or susceptor 130, thus isolating the lower interior space 102 from the upper interior space 104.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. A reaction chamber, comprising:
a lower chamber having an interior space defined by a bottom surface and horizontally-oriented sidewalls that extend upwards from the bottom surface;
a lid opposite from the bottom surface and in direct contact with the sidewalls, wherein the lid comprises an opening;
a spacer plate, comprising:
a first end connected to the lid; and
a second end extending towards the opening of the lid, wherein the second end comprises a horizontally-oriented section and a ridge extending downward from the horizontally-oriented section;
a susceptor, comprising:
a primary region comprising a heating element; and
an outer edge extending away from the primary region, wherein the outer edge comprises a groove that is sized to mate with the ridge; and
a seal positioned within the groove.

2. The reaction chamber according to claim 1, wherein the spacer plate is connected to the lid with a fastener formed from a non-conducting material.

3. The reaction chamber according to claim 1, further comprising an electrical insulator disposed between the spacer plate and the lid.

4. The reaction chamber according to claim 1, wherein the seal comprises an e-ring formed from a metal material.

5. The reaction chamber according to claim 1, wherein the seal contacts the ridge of the spacer plate.

6. The reaction chamber according to claim 1, wherein the groove and the ridge have complementary shapes.

7. A reaction chamber, comprising:
a lower chamber having an interior space defined by a bottom surface and horizontally-oriented sidewalls that extend upwards from the bottom surface;
a spacer plate, comprising:
a first end connected to the lower chamber; and
a second end extending towards the opening of the lid, wherein the second end comprises a horizontally-oriented section and a ridge extending downward from the horizontally-oriented section;
a susceptor, comprising:
a primary region comprising a heating element and having a first height; and
an outer edge extending horizontally away from the primary region, wherein the outer edge has second height that is less than the first height;
a flow control ring positioned on the outer edge and comprising an upward facing surface; and
a seal positioned on the flow control ring.

8. The reaction chamber according to claim 7, wherein the flow control ring comprises a groove within the upward facing surface.

9. The reaction chamber according to claim 8, wherein the groove is sized to mate with the ridge.

10. The reaction chamber according to claim 8, wherein the groove and the ridge have complementary shapes.

11. The reaction chamber according to claim 8, wherein the seal is disposed within the groove.

12. The reaction chamber according to claim 7, wherein the spacer plate comprises a through-hole configured for flowing a gas.

13. The reaction chamber according to claim 7, wherein the seal contacts the ridge of the spacer plate.

14. A reaction chamber, comprising:
a lower chamber having an interior space defined by a bottom surface and horizontally-oriented sidewalls that extend upwards from the bottom surface;
a lid opposite from the bottom surface and in direct contact with the sidewalls, wherein the lid comprises an opening;
a spacer plate, comprising:
a first end connected to the lid; and
a second end extending towards the opening of the lid, wherein the second end comprises a horizontally-oriented section and a first ridge extending downward from the horizontally-oriented section;
a susceptor, comprising:
a primary region comprising a heating element and having a first height; and
an outer edge, having a second height that is less than the first height, extending away from the primary region, and
an e-ring seal disposed between the first ridge and the outer edge.

15. The reaction chamber according to claim 14, further comprising a flow control ring positioned on the outer edge and comprising an upward facing surface.

16. The reaction chamber according to claim 15, wherein upward facing surface comprises a groove that is sized to mate with the first ridge.

17. The reaction chamber according to claim 14, wherein the susceptor further comprises a second ridge extending upwards from the outer edge, and wherein the groove is formed by a vertical sidewall of the primary region and the second ridge.

18. The reaction chamber according to claim 17, wherein the groove and the first ridge have complementary shapes.

19. The reaction chamber according to claim 14, wherein the spacer plate is connected to the lid with a fastener formed from a non-conducting material.

20. The reaction chamber according to claim 14, further comprising an electrical insulator disposed between the spacer plate and the lid.
